(19) United States
(12) Patent Application Publication
(10) Pub. No.: US 2013/0146946 A1
(43) Pub. Date: Jun. 13, 2013

(54) SEMICONDUCTOR DEVICE AND METHOD FOR FABRICATING SAME

(71) Applicant: Panasonic Corporation, Osaka (JP)

(72) Inventors: NAOHIRO TSURUMI, Toyama (JP); SATOSHI NAKAZAWA, Osaka (JP); RYO KAJITANI, Osaka (JP); YOSHIHARU ANDA, Osaka (JP); TETSUZO UEDA, Osaka (JP)

(73) Assignee: PANASONIC CORPORATION, Osaka (JP)

(21) Appl. No.: 13/759,100

(22) Filed: Feb. 5, 2013

Related U.S. Application Data
(63) Continuation of application No. PCT/JP2011/003131, filed on Jun. 2, 2011.

(30) Foreign Application Priority Data
Aug. 6, 2010 (JP) 2010-177105

(51) Int. Cl. H01L 29/78; H01L 29/66

(52) U.S. Cl. CPC H01L 29/78; H01L 29/66431
USPC 257/192; 438/172

(57) ABSTRACT

A semiconductor device includes: a buffer layer provided on a substrate and made of a group III-V nitride semiconductor; a first semiconductor layer provided on the buffer layer and made of a group III-V nitride semiconductor; a second semiconductor layer provided on the first semiconductor layer and made of a group III-V nitride semiconductor; a back electrode provided on a back surface of the substrate and connected to a ground; a source electrode and a drain electrode provided on the second semiconductor layer so as to be apart from each other; a gate electrode provided on the second semiconductor layer; and a plug which passes through the second semiconductor layer, the first semiconductor layer, and the buffer layer, and reaches at least the substrate to electrically connect the source electrode and the back electrode.

### CROSS-REFERENCE TO RELATED APPLICATIONS

This is a continuation of International Application No. PCT/JP2011/003131 filed on Jun. 2, 2011, which claims priority to Japanese Patent Application No. 2010-177105 filed on Aug. 6, 2010. The entire disclosures of these applications are incorporated by reference herein.

### BACKGROUND

The techniques described in the present specification relate to field-effect type semiconductor devices made of a group III-V nitride semiconductor.

Consideration has been made to apply group III-V nitride semiconductors, such as gallium nitride (GaN), aluminum nitride (AlN), and indium nitride (InN), which are mixed crystals represented by a general formula of AlₓGa_{1-x-y}In_{y}N (where, 0≦x≦1, 0≦y≦1, and 0≦x+y≦1), not only to short wavelength optical elements because of their physical features, i.e., wide band gaps and direct transition band structures, but also to electronic devices because of their having high breakdown electric fields and high saturated electron velocity.

In particular, hetero-junction field effect transistors (hereinafter referred to as HFETs) using two dimensional electron gas (hereinafter referred to as 2DEG) present at the interface between an AlₓGa₁₋ₓN layer (where 0≦x≦1) and a GaN layer which are sequentially and epitaxially grown on a semi-insulating substrate, have been developed as high output devices and high frequency devices. In this HFET, in addition to electron supply from a carrier supply layer (an N-type AlGaN Schottky layer), a charge is supplied due to polarization effects of spontaneous polarization and piezoelectric polarization. The electron density in a channel of the HFET exceeds 10¹³ cm⁻², which is about one digit greater than the electron density in a channel of an AlGaAs/GaAs-based HFET.

Thus, it is expected that the HFET using a group III-V nitride semiconductor may have a higher drain current density, compared to a GaAs-based HFET, and an element whose maximum drain current exceeds 1 A/mm has been reported (see Non-Patent Document 1: Yuji ANDO et al., Characterization of High Breakdown Voltage AlGaN/GaN Heterojunction FETs with a Field Plate Gate, Technical Report of the Institute of Electronics, Information and Communication Engineers (IEICE), ED2002-214, CPM2002-105 (2002-10), pp. 29-34). Further, the group III-V nitride semiconductor has a wide band gap (for example, the band gap of GaN is 3.4 eV), and therefore the group III-V nitride semiconductor exhibits high breakdown voltage characteristics. In the HFET using the group III-V nitride semiconductor, the breakdown voltage between a gate electrode and a drain electrode can be 100 V or more (see Non-Patent Document 1). Due to these electrical characteristics of high breakdown voltage and high current density, it is being considered to use electronic devices represented mainly by HFETs using a group III-V nitride semiconductor, as high frequency elements, and as elements whose dimensions are smaller than those of conventional elements and which can operate at a high electric power.

However, although the electronic devices using the group III-V nitride semiconductor are considered to have potential as a high frequency, high output, or high electric power element, various techniques are necessary to achieve such an element. As one of techniques for achieving such an element having high frequency characteristics, high output characteristics, and high electric power characteristics, a technique using a via hole structure has been known (see Non-Patent Document 1).

An FET having such a conventional via hole structure will be described below with reference to FIG. 5. FIG. 5 is a cross-sectional view of a structure of a conventional FET having a via hole structure.

As shown in FIG. 5, the conventional FET includes a channel layer 3 made of a group III-V nitride semiconductor and provided on a high resistance substrate 1 made of silicon (Si), and a Schottky layer 5 made of a group III-V nitride semiconductor and provided on the channel layer 3.

A Schottky electrode 7 is provided on the Schottky layer 5, and a source electrode 11 and a drain electrode 13 of ohmic type are located on the lateral sides of the Schottky electrode 7 on the Schottky layer 5. A via hole 25 is selectively formed in parts of regions of the high resistance substrate 1, a buffer layer, the channel layer 3, and the Schottky layer 5 located under the source electrode 11. A plug 9 is buried in the via hole 25 to be connected to a back electrode 15. The source electrode 11 of the FET is connected to a ground power supply through the plug 9 and the back electrode 15.

Since source inductance can be reduced more in the conventional FET, compared to a FET in which a source electrode is grounded by wire, an improvement of about 2 dB in linear gain has been reported (see Non-Patent Document 2: Masumi FUKUDA et al., Basics of GaAs Field-Effect Transistors, the Institute of Electronics, Information and Communication Engineers (IEICE), p. 214 (1992).

### SUMMARY

However, the conventional semiconductor device using a via hole has the following problem, that is, if a Si substrate which is less in cost is used in the semiconductor device, output is reduced compared to a semiconductor element in which a SiC substrate is used, because the Si substrate has poorer thermal conductivity than the SiC substrate.

In view of the above problem, the present disclosure is intended to reduce the output reduction caused by heat in a semiconductor device including a group III-V nitride semiconductor.

FIG. 6 shows a comparison between output of a conventional semiconductor device operated in a normal mode and output of the conventional semiconductor device operated a pulse mode. It is known from the results shown in FIG. 6 that the output reduction is reduced in the pulse operation. This may be because an increase in temperature of the substrate is reduced more in the pulse operation than in the normal operation.

FIG. 7 shows a temperature distribution in the semiconductor device during operation. In FIG. 7, a dark color portion, which is a high temperature portion, is an active region (mainly a region between source and drain), and it is known from the figure that heat is generated in the active region. In view of this, the inventors of the present application conducted original studies to find the present disclosure.

A semiconductor device according to one aspect of the present disclosure includes a substrate; a first semiconductor layer provided over an upper surface of the substrate and made of a group III-V nitride semiconductor; a second semiconductor layer provided on the first semiconductor layer and made of a group III-V nitride semiconductor; a back electrode provided on a back surface of the substrate and connected to a ground; a source electrode and a drain electrode which are provided on the second semiconductor layer and spaced apart from each other; a gate electrode provided on the second semiconductor layer, located between the source electrode and the drain electrode, and brought into Schottky contact with the second semiconductor layer; and a plug which passes through the second semiconductor layer and the first semiconductor layer and reaches at least the substrate to electrically connect the source electrode and the back electrode.

In this configuration, the source electrode is connected to the back electrode and the ground through the plug, without using a wire over the second semiconductor layer. Thus, the source inductance can be more reduced, compared to the case where the source electrode is grounded through a wire.

Further, since the plug is provided in a region where heat is generated between the source electrode and the drain electrode during an operation, that is, a region under the source electrode, the heat is transferred to the back electrode through the plug. Thus, a temperature increase during the operation can be reduced. As a result, the output reduction of the semiconductor device having the above configuration can be reduced, compared to the conventional semiconductor devices.

A method for fabricating a semiconductor device according to one aspect of the present disclosure includes: forming a back electrode on a back surface of a substrate; forming a first semiconductor layer made of a group III-V nitride semiconductor over an upper surface of the substrate; forming a second semiconductor layer made of a group III-V nitride semiconductor on the first semiconductor layer; forming a source electrode and a drain electrode on the second semiconductor layer so that the source electrode and the drain electrode are spaced apart from each other; forming a gate electrode on the second semiconductor layer; and forming a plug which is connected to the source electrode, passes through the first semiconductor layer and the second semiconductor layer, and reaches at least a portion of the substrate.

According to this method, it is possible to form a structure which can easily dissipate heat generated during an operation to the back electrode through the plug. It is also possible to fabricate a semiconductor device with reduced source inductance.

In a semiconductor device according to one aspect of the present disclosure, an output reduction due to heat can be reduced more than in a conventional semiconductor device.

### BRIEF DESCRIPTION OF THE DRAWINGS

FIGS. 1A and 1B respectively show a cross-sectional view and a layout of a hetero-junction field effect transistor (an HFET) according to the first embodiment of the present disclosure, for schematically illustrating a configuration of the HFET. FIGS. 1C and 1D show enlarged cross-sectional views of example connecting portions between a source electrode and a plug.

FIG. 2 is a cross-sectional view of an HFET according to the second embodiment of the present disclosure, for schematically illustrating a configuration of the HFET.

FIG. 3 is a cross-sectional view of an HFET according to the third embodiment of the present disclosure, for schematically illustrating a configuration of the HFET.

FIGS. 4A and 4B show cross-sectional views of an HFET according to the fourth embodiment of the present disclosure, for schematically illustrating a configuration of the HFET.

FIG. 5 is a cross-sectional view of a conventional FET having a via hole structure, for illustrating a configuration of the conventional FET.

FIG. 6 shows a comparison between output of a conventional semiconductor device operated in a normal mode and output of the conventional semiconductor device operated in a pulse mode.

FIG. 7 shows a temperature distribution in a semiconductor device during operation.

### DETAILED DESCRIPTION

Embodiments of the present disclosure will be described below with reference to the drawings.

### First Embodiment

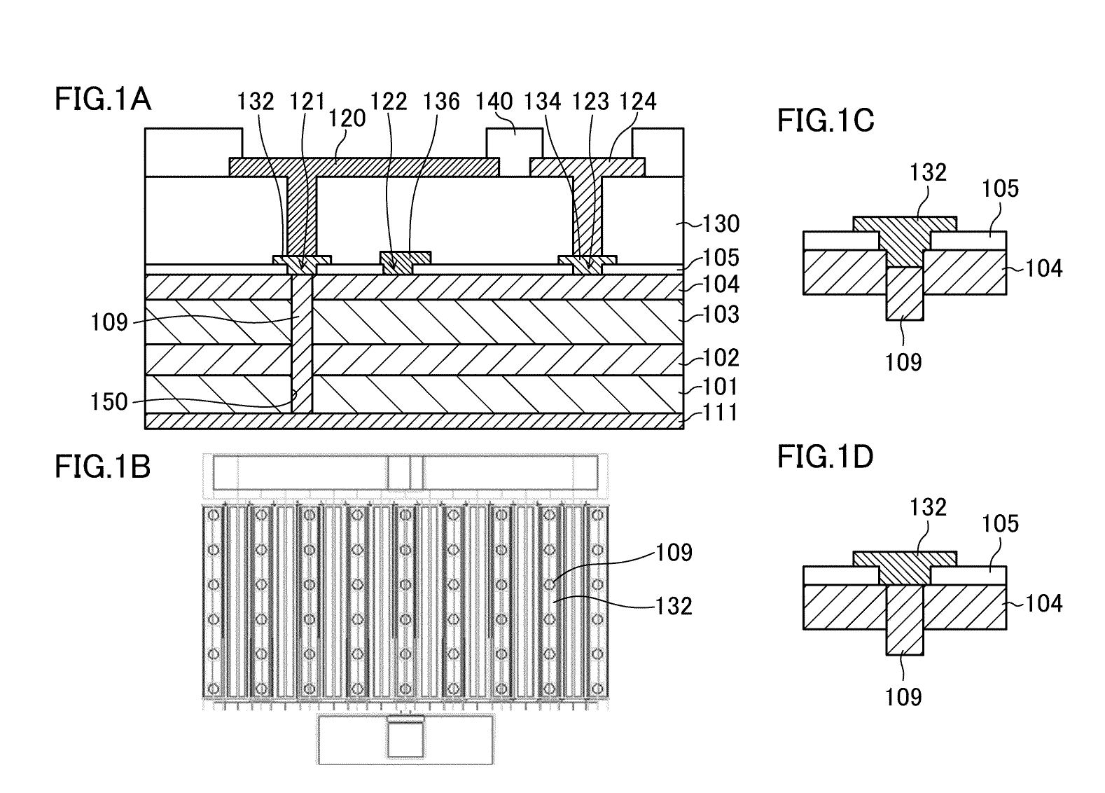

FIGS. 1A and 1B respectively show a cross-sectional view and a layout of a hetero-junction field effect transistor (an HFET) according to the first embodiment of the present disclosure, for schematically illustrating a configuration of the HFET. FIGS. 1C and 1D show enlarged cross-sectional views of example connecting portions between a source electrode and a plug. FIG. 1A is a horizontal cross-section passing through a plug 109 in FIG. 1B.

As shown in FIGS. 1A and 1B, an HFET of the present embodiment includes: a high resistance substrate 101 made, for example, of silicon (Si); a buffer layer 102 provided on the high resistance substrate 101 and made of a high resistive aluminum gallium nitride (AlₓGa₁₋ₓN (0≦x≦1)); a channel layer (a first semiconductor layer) 103 provided on the buffer layer 102 and made of an undoped gallium nitride (GaN); and a Schottky layer (a second semiconductor layer) 104 provided on the channel layer 103 and made of an N-type aluminum gallium nitride (Al_{y}Ga_{1-y}N (0<y≦1)).

The thickness of the high resistance substrate 101 is 500 μm, for example. The thickness of the buffer layer 102 is 500 nm, for example. The thickness of the channel layer 103 is 1000 nm, for example. The thickness of the Schottky layer 104 is 25 nm, for example.

The buffer layer 102 is provided to reduce the lattice mismatch between the high resistance substrate 101, and the channel layer 103 and the Schottky layer 104. Further, a channel made of 2DEG is formed near the interface of the channel layer 103 with the Schottky layer 104 which is in hetero junction with the channel layer 103. Here, that the substrate and the buffer layer are highly resistive means that almost no current flows during a normal operation of the HFET, and a so-called semi-insulating layer is also called a high resistance layer.

A first insulating film 105 made of silicon nitride (SiN) with a thickness of 100 nm is provided on the Schottky layer 104. Openings 121, 122, 123 are formed in the first insulating film 105, spaced apart from one another.

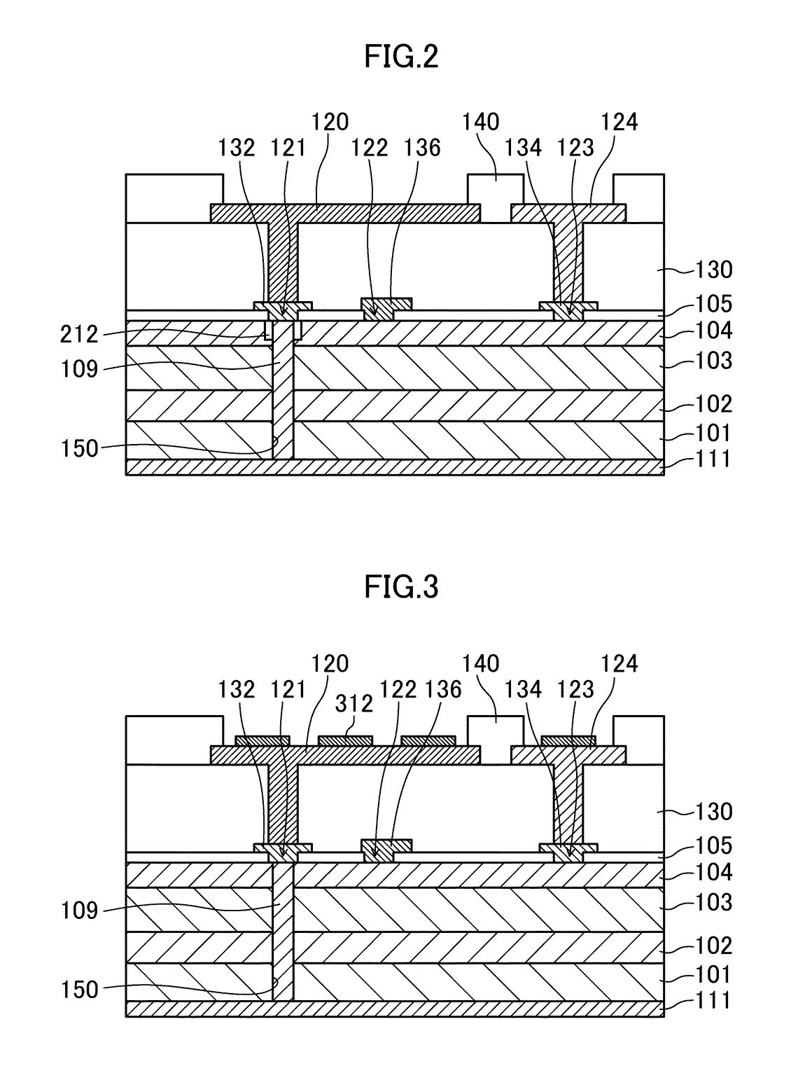

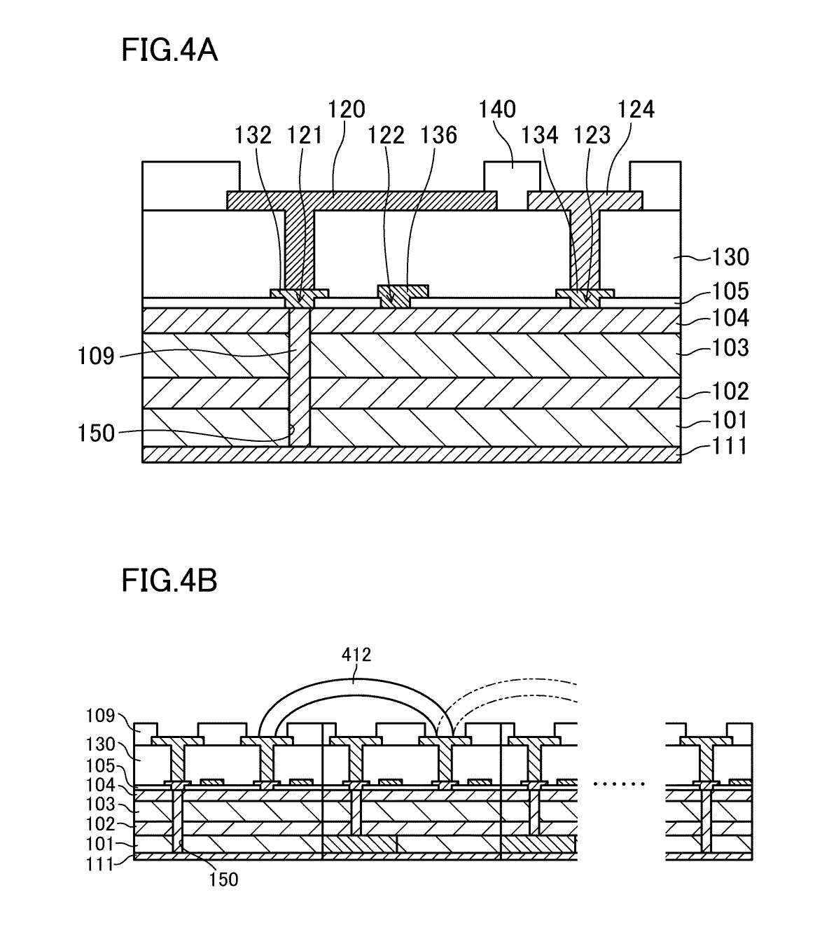

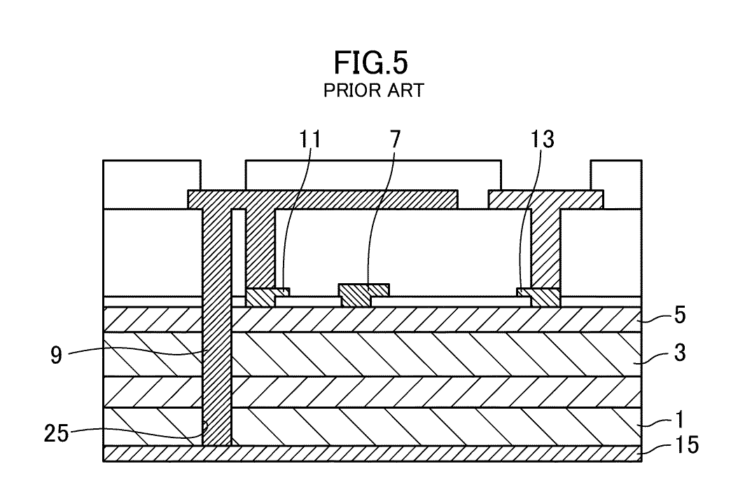

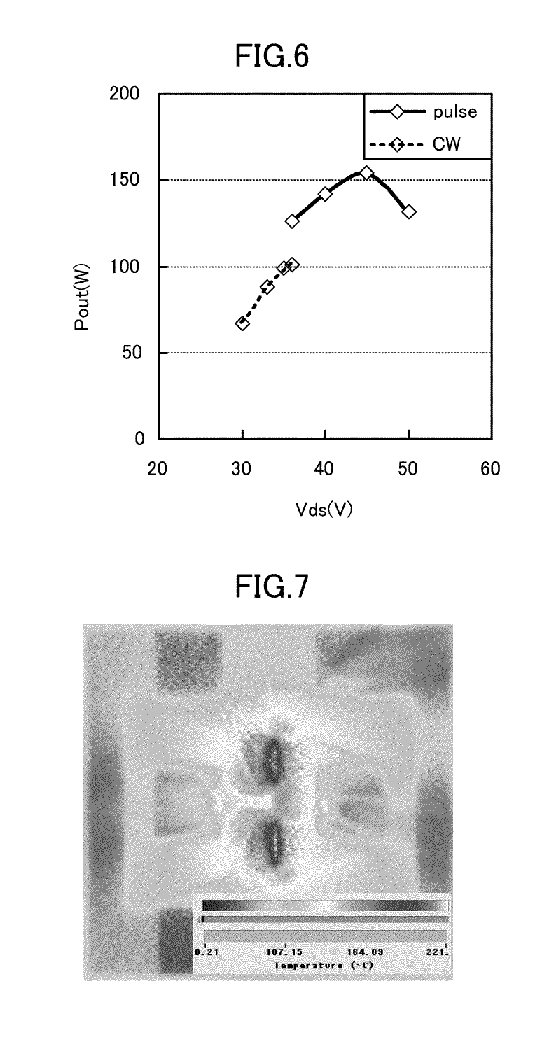

A source electrode 132 is provided on the Schottky layer 104 in the opening 121, and on part of the first insulating film 105. There is a case in which part of the source electrode 132 is inserted in the via hole 150. For example, part of the source electrode 132 may be inserted in a portion of the via hole 150 surrounded by the Schottky layer 104 as shown in FIG. 1C, or the source electrode 132 may not be inserted in the via hole 150 as shown in FIG. 1D. The same applies to the HFET shown in FIG. 2, FIG. 3, and FIGS. 4A and 4B described later. More specifically, the source electrode 132 and the plug 109 in the via hole 150 may be connected through a metal, such as gold (Au).

The source electrode 132 has a layered structure made, for example, of titanium (Ti) and aluminum (Al) so that the source electrode 132 may exhibit ohmic characteristics with respect to the Schottky layer 104 made of N-type Al_{y}Ga_{1-y}N. The thickness of the source electrode 132 located on the Schottky layer 104 is, for example, 200 nm from the upper surface of the Schottky layer 104.

A gate electrode 136 is provided on the Schottky layer 104 in the opening 122, and on part of the first insulating film 105. The thickness of the gate electrode 136 located on the Schottky layer 104 is 400 nm. The gate electrode 108 has a layered structure made, for example, of nickel (Ni) and gold (Au) so that the gate electrode 136 may exhibit Schottky characteristics with respect to the Schottky layer 104.

A drain electrode 134 is provided on the Schottky layer 104 in the opening 123, and on part of the first insulating film 105. Similar to the source electrode 132, the drain electrode 134 has a layered structure made, for example, of Ti and Al so that the drain electrode 134 may be in ohmic contact with the Schottky layer 104. The thickness of part of the drain electrode 134 that is located on the Schottky layer 104 is 200 nm, for example.

A back electrode 111 made, for example, of chromium (Cr)/gold (Au) with a thickness of about 200 nm is provided on the back surface of the high resistance substrate 101. The source electrode 132 and the back electrode 111 are connected to each other by the plug 109 which passes through the Schottky layer 104, the channel layer 103, the buffer layer 102, and the high resistance substrate 101. The back electrode 111 is connected to a ground wire. The plug 109 has a layered structure made, for example, of Cr and Au. As shown in FIG. 1B, a plurality of plugs 109 may be provided in one source electrode 132.

A second insulating film 130 made, for example, of SiN with a thickness of 500 nm is provided on the first insulating film 105, on the gate electrode 136, on the source electrode 132, and on the drain electrode 134. A source interconnect 120 connected to the source electrode 132 through a contact plug, a gate interconnect (not shown) connected to the gate electrode 136 through a contact plug, and a drain interconnect 124 connected to the drain electrode 134 through a contact plug, are formed on the second insulating film 130. The gate interconnect, the source interconnect 120, and the drain interconnect 124 are located so as not to be connected to each other. If the gate interconnect, the source interconnect 120, and the drain interconnect 124 are formed in two or more interconnect layers, it is preferable that these interconnects do not intersect each other to reduce parasitic capacitance.

A third insulating film 140 with a thickness of 400 nm, for example, is provided on the second insulating film 130.

In the HFET of the present embodiment, a current passes through the interface between the channel layer 103 and the Schottky layer 104, where 2DEG is generated, to flow between the source electrode 132 and the drain electrode 134. Further, the amount of current flowing between the source and the drain is controlled by applying a voltage to the gate electrode 136.

In the HFET of the present embodiment, the source electrode 132 is connected to the back electrode 111 and the ground wire through the plug 109, without using a wire on the second insulating film 130. Thus, the length of the source interconnect can be shortened more than in the case where the source electrode 132 is grounded through a wire. Accordingly, the source inductance is reduced. As a result, it is possible to improve the linear gain. Further, since the plug 109 is provided directly under the source electrode 132, heat generated during the operation is transferred to the back electrode 111 through the plug 109, and is efficiently dissipated. Since the heat can be efficiently dissipated through the plug 109 provided in a region where the heat is generated during the operation, the output reduction of the HFET of the present embodiment is significantly reduced, compared to the conventional HFETs.

In the HFET of the present embodiment, the plug 109 passes through the high resistance substrate 101. However, in the case where a conductive substrate is used, the plug 109 does not need to pass through the substrate, but only needs to be in contact with the substrate.

Further, the high resistance substrate 101 made of Si may be replaced with a conductive substrate, a semi-insulating substrate, such as a GaN substrate, or an insulating substrate, such as a sapphire substrate. In the case where the GaN substrate is used, the buffer layer is not necessarily needed.

In fabricating the HFET of the present embodiment, the back electrode 111 made of a metal is formed on the back surface of the high resistance substrate 101 by chemical vapor deposition (CVD), etc. Next, the buffer layer 102 made of a group III-V nitride semiconductor, such as AlₓGa₁₋ₓN (0≦x≦1), the channel layer 103 made of a group III-V nitride semiconductor, such as GaN, and the Schottky layer 104 made of a group III-V nitride semiconductor, such as N-type Al_{y}Ga_{1-y}N (0≦y≦1), are sequentially formed on the high resistance substrate 101 by metal-organic CVD (MOCVD), etc.

Then, the first insulating film made of SiN, etc., is formed on the Schottky layer 104, and thereafter the openings 121, 122, 123 are formed by lithography and etching. After that, the source electrode 132 is formed on the Schottky layer 104 in the opening 121, and the drain electrode 134 is formed on the Schottky layer 104 in the opening 123. Then, the gate electrode 136 is formed on the Schottky layer 104 in the opening 122.

Next, part of the source electrode 132, and the Schottky layer 104, the channel layer 103, the buffer layer 102, and the high resistance substrate 101 which are located under the source electrode 132, are removed to form the via hole 150 which reaches the back electrode 111. After that, the plug 109 is formed in the via hole 150.

Then, the second insulating film 130 is formed on the first insulating film 105, and thereafter, the source interconnect 120 connected to the source electrode 132, the drain interconnect 124 connected to the drain electrode 134, and the gate interconnect connected to the gate electrode 136 are formed on the second insulating film 130.

### Second Embodiment

FIG. 2 is a cross-sectional view of an HFET according to the second embodiment of the present disclosure, for schematically illustrating a configuration of the HFET. The HFET of the present embodiment is different from the HFET of the first embodiment in that a high resistance region 212 is formed in a Schottky layer 104 located below the opening 121 where a via hole 150 is formed. The other configurations, except the high resistance region 212, are similar to those of the HFET of the first embodiment.

Specifically, as shown in FIG. 2, the HFET of the present embodiment includes a high resistance substrate 101, a buffer layer 102 provided on the high resistance substrate 101, a channel layer 103 provided on the buffer layer 102, and a Schottky layer 104 provided on the channel layer 103.

A first insulating film 105 is provided on the Schottky layer 104. Openings 121, 122, 123 are formed in the first insulating film 105, spaced apart from one another.

A source electrode 132 is provided on the Schottky layer 104 in the opening 121, and on part of the first insulating film 105. A gate electrode 136 is provided on the Schottky layer 104 in the opening 122, and on part of the first insulating film 105. A drain electrode 134 is provided on the Schottky layer 104 in the opening 123, and on part of the first insulating film 105.

A back electrode 111 is provided on the back surface of the high resistance substrate 101. The source electrode 132 and the back electrode 111 are connected to each other through a plug 109 which passes through the Schottky layer 104, the channel layer 103, the buffer layer 102, and the high resistance substrate 101.

A second insulating film 130 is provided on the first insulating film 105, on the gate electrode 136, on the source electrode 132, and on the drain electrode 134. A source interconnect 120 connected to the source electrode 132 through a contact plug, a gate interconnect (not shown) connected to the gate electrode 136 through a contact plug, and a drain interconnect 124 connected to the drain electrode 134 through a contact plug, are provided on the second insulating film 130. If the gate interconnect, the source interconnect 120, and the drain interconnect 124 are formed in two or more interconnect layers, these interconnects are provided so as not to intersect each other.

At least part of a portion of the Schottky layer 104 which is in contact with the plug 109 (a portion near the region where a contact hole is formed) serves as the high resistance region 212 whose resistance is higher than a resistance of the other part of the Schottky layer 104.

The high resistance region 212 is formed by implanting ions, such as boron (B), into the Schottky layer 104, or performing dry etching on the Schottky layer 104 to form a via hole 150, after the opening 121 is formed in the method for fabricating the HFET described in the first embodiment.

In the HFET of the present embodiment, the source electrode 132 is connected to the back electrode 111 and the ground wire through the plug 109, without using a wire on the second insulating film 130. Thus, the source inductance is reduced more than in the case where the source electrode 132 is grounded through a wire. Further, since the plug 109 is provided directly under the source electrode 132, heat generated during the operation is transferred to the back electrode 111 through the plug 109, and efficiently dissipated. Since the heat can be efficiently dissipated through the plug 109 provided in a region where the heat is generated during the operation, the output reduction of the HFET of the present embodiment is significantly reduced, compared to the conventional HFETs. Moreover, since the high resistance region 212 is provided around a portion of the plug 109 which passes through the Schottky layer 104, an increase in leakage current through the semiconductor layer is reduced.

### Third Embodiment

FIG. 3 is a cross-sectional view of an HFET according to the third embodiment of the present disclosure, for schematically illustrating a configuration of the HFET. The HFET of the present embodiment is different from the HFET of the first embodiment in that a warpage-reducing layer 312 which compensates the warpage of the substrate is provided on each of the source interconnect 120 and the drain interconnect 124. The other configurations, except the warpage-reducing layer 312, are similar to those of the HFET of the first embodiment.

Specifically, as shown in FIG. 3, the HFET of the present embodiment includes a high resistance substrate 101, a buffer layer 102 provided on the high resistance substrate 101, a channel layer 103 provided on the buffer layer 102, and a Schottky layer 104 provided on the channel layer 103.

A first insulating film 105 is provided on the Schottky layer 104. Openings 121, 122, 123 are formed in the first insulating film 105, spaced apart from one another.

A source electrode 132 is provided on the Schottky layer 104 in the opening 121, and on part of the first insulating film 105. A gate electrode 136 is provided on the Schottky layer 104 in the opening 122, and on part of the first insulating film 105. A drain electrode 134 is provided on the Schottky layer in the opening 123, and on part of the first insulating film 105.

A back electrode 111 is provided on the back surface of the high resistance substrate 101. The source electrode 132 and the back electrode 111 are connected to each other through a plug 109 which passes through the Schottky layer 104, the channel layer 103, the buffer layer 102, and the high resistance substrate 101.

A second insulating film 130 is provided on the first insulating film 105, on the gate electrode 136, on the source electrode 132, and on the drain electrode 134. A source interconnect 120 connected to the source electrode 132 through a contact plug, a gate interconnect (not shown) connected to the gate electrode 136 through a contact plug, and a drain interconnect 124 connected to the drain electrode 134 through a contact plug, are provided on the second insulating film 130. The gate interconnect, the source interconnect 120, and the drain interconnect 124 are located so as not to be connected to one another.

Further, in the HFET of the present embodiment, a warpage-reducing layer 312 made of a material having a great stress which compensates warpage of the substrate is provided on each of the source interconnect 120 and the drain interconnect 124. The warpage-reducing layer 312 only needs to have a stress that is greater than the stresses of at least the high resistance substrate 101, the channel layer 103, the Schottky layer 104, etc., and be able to apply a stress in a direction which reduces the warpage of the high resistance substrate 101. The number of the warpage-reducing layers 312, the thickness and the area of the warpage-reducing layer 312 are not specifically limited, but may be appropriately adjusted. The warpage-reducing layer 312 may be made of WSi, for example.

In HFETs, the back surface of the high resistance substrate 101 may sometimes be warped inward. However, in the HFET of the present embodiment, the warpage-reducing layer 312 is provided to effectively reduce the warping of the substrate. Thus, for example when the HFET of the present embodiment is used in other electronic devices, it is possible to ensure connection with high reliability.

### Fourth Embodiment

FIGS. 4A and 4B show cross-sectional views of an HFET according to the fourth embodiment of the present disclosure, for schematically illustrating a configuration of the HFET. The HFET of the present embodiment is different from the HFET of the first embodiment in that an air bridge 412 is provided on the drain interconnect 124. The other configurations, except the air bridge 412, are similar to those of the HFET of the first embodiment. Although, in fact, the air bridge 412 extends from the drain interconnect 124 as shown in FIG. 4B, the air bridge 412 is not shown in FIG. 4A to avoid complexity.

Specifically, as shown in FIG. 4, the HFET of the present embodiment includes a high resistance substrate 101, a buffer layer 102 provided on the high resistance substrate 101, a channel layer 103 provided on the buffer layer 102, and a Schottky layer 104 provided on the channel layer 103.

A first insulating film 105 is provided on the Schottky layer 104. Openings 121, 122, 123 are formed in the first insulating film 105, spaced apart from one another.

A source electrode 132 is provided on the Schottky layer 104 in the opening 121, and on part of the first insulating film 105. A gate electrode 136 is provided on the Schottky layer 104 in the opening 122, and on part of the first insulating film 105. A drain electrode 134 is provided on the Schottky layer in the opening 123, and on part of the first insulating film 105.

A back electrode 111 is provided on the back surface of the high resistance substrate 101. The source electrode 132 and the back electrode 111 are connected to each other through a plug 109 which passes through the Schottky layer 104, the channel layer 103, the buffer layer 102, and the high resistance substrate 101.

A second insulating film 130 is provided on the first insulating film 105, on the gate electrode 136, on the source electrode 132, and on the drain electrode 134. A source interconnect 120 connected to the source electrode 132 through a contact plug, a gate interconnect (not shown) connected to the gate electrode 136 through a contact plug, and a drain interconnect 124 connected to the drain electrode 134 through a contact plug, are provided on the second insulating film 130. The gate interconnect, the source interconnect 120, and the drain interconnect 124 are located so as not to be connected to one another.

Further, the HFET of the present embodiment is provided with an air bridge 412 made of a conductive material and extending from one drain interconnect 124 to another drain interconnect 124 which is spaced apart from the one drain interconnect 124. That is, a plurality of drain interconnects 124 are connected to each other by the air bridges 412. There is a hollow under the air bridge 412. Thus, the air bridge 412 crosses over the source interconnect 120 without being connected to the source interconnect 120.

In the HFET of the present embodiment, the drain interconnects 124 are connected to each other by the air bridge 412. Thus, heat dissipation is more improved. As a result, it is possible to reduce the output reduction due to heat generated during operation more efficiently.

The air bridge 412 may be replaced with a commonly-used contact or metal wire to connect the drain interconnects.

The foregoing descriptions are example embodiments. The shape, the material, the film thickness, etc. of each component is capable of appropriate modification without departing from the scope of the disclosure. Further, configurations described in the above embodiments may be combined to each other. An insulating substrate made, for example, of sapphire may be used as the substrate.

The HFET of the present disclosure is superior in high frequency characteristics, and can be used in various electronic devices.

What is claimed is:

1. A semiconductor device comprising:
a substrate;
a first semiconductor layer provided over an upper surface of the substrate and made of a group III-V nitride semiconductor;
a second semiconductor layer provided on the first semiconductor layer and made of a group III-V nitride semiconductor;
a back electrode provided on a back surface of the substrate and connected to a ground;
a source electrode and a drain electrode which are provided on the second semiconductor layer and spaced apart from each other;
a gate electrode provided on the second semiconductor layer, located between the source electrode and the drain electrode, and brought into Schottky contact with the second semiconductor layer; and
a plug which passes through the second semiconductor layer and the first semiconductor layer and reaches at least the substrate to electrically connect the source electrode and the back electrode.

2. The semiconductor device of claim 1, wherein
the first semiconductor layer is made of GaN, and
the second semiconductor layer is made of N-type AlₓGa₁₋ₓN (0≦x≦1).

3. The semiconductor device of claim 1, further comprising:
a source interconnect provided above the second semiconductor layer and connected to the source electrode;
a drain interconnect provided above the second semiconductor layer and connected to the drain electrode; and
a gate interconnect provided above the second semiconductor layer and connected to the gate electrode, wherein
the source interconnect, the drain interconnect, and the gate interconnect are located so as not to intersect with one another.

4. The semiconductor device of claim 1, wherein
a resistance of a plug contacting portion of the second semiconductor layer is higher than a resistance of the other portion of the second semiconductor layer.

5. The semiconductor device of claim 3, further comprising:
a warpage-reducing layer provided at least on the source interconnect or on the drain interconnect, for applying a stress to the source interconnect or the drain interconnect in a direction which reduces warpage of the substrate.

6. The semiconductor device of claim 3, wherein
the drain interconnect includes a plurality of drain interconnects, and
the semiconductor device further includes an air bridge which connects the drain interconnects spaced apart from each other.

7. The semiconductor device of claim 1, wherein
the plug further passes through the substrate.

8. The semiconductor device of claim 1, wherein
the substrate is conductive, and
the plug reaches a portion of the substrate.

9. The semiconductor device of claim 1, further comprising:
a buffer layer provided on the upper surface of the substrate and made of a group III-V nitride semiconductor, wherein
the first semiconductor layer is provided on the buffer layer, and
the plug passes through the buffer layer.

10. A method for fabricating a semiconductor device, comprising:
forming a back electrode on a back surface of a substrate;
forming a first semiconductor layer made of a group III-V nitride semiconductor over an upper surface of the substrate;
forming a second semiconductor layer made of a group III-V nitride semiconductor on the first semiconductor layer;
forming a source electrode and a drain electrode on the second semiconductor layer so that the source electrode and the drain electrode are spaced apart from each other;
forming a gate electrode on the second semiconductor layer; and
forming a plug which is connected to the source electrode, passes through the first semiconductor layer and the second semiconductor layer, and reaches at least a portion of the substrate.

11. The method of claim 10, further comprising:
forming a buffer layer made of a group III-V nitride semiconductor on the upper surface of the substrate, wherein
the first semiconductor layer is formed on the buffer layer, and
the plug passes through the buffer layer.
